(19) United States
(12) Patent Application Publication
(10) Pub. No.: US 2025/0350046 A1
(43) Pub. Date: Nov. 13, 2025

(54) CONNECTION STRUCTURE

(71) Applicant: SUMITOMO ELECTRIC INDUSTRIES, LTD., Osaka (JP)

(72) Inventors: Masamichi YAMAMOTO, Osaka (JP); Kyouichirou NAKATSUGI, Osaka (JP); Takayoshi KOINUMA, Osaka (JP); Masahiro MATSUMOTO, Osaka (JP); Shiho HATTORI, Osaka (JP); Narumi YOSHIDA, Osaka (JP)

(73) Assignee: SUMITOMO ELECTRIC INDUSTRIES, LTD., Osaka (JP)

(21) Appl. No.: 18/868,699

(22) PCT Filed: May 30, 2022
(86) PCT No.: PCT/JP2022/021909

§ 371 Date: Nov. 22, 2024

(51) Int. Cl. H01R 12/53; H01B 7/02; H01B 7/282

(52) U.S. Cl. CPC H01R 12/53; H01B 7/02; H01B 7/282

(57) ABSTRACT

A connection structure includes a plurality of insulated electric wires, a base material, a plurality of connected portions disposed on the base material, and a sealing member. Each of the plurality of insulated electric wires has a central conductor and an insulating layer covering a peripheral surface of the central conductor. The central conductor is exposed from the insulating layer at a tip portion of each of the plurality of insulated electric wires in an axial direction. The plurality of connected portions are arranged in rows. The tip portions of the plurality of insulated electric wires are respectively soldered to the plurality of connected portions. The sealing member is disposed on the base material to cover the tip portions of the plurality of insulated electric wires and the plurality of connected portions.

### TECHNICAL FIELD

The present disclosure relates to a connection structure.

### BACKGROUND ART

For example, Japanese Patent Laying-Open No. 2015-201280 (PTL 1) describes a connection structure. The connection structure described in PTL 1 has a plurality of insulated electric wires, a printed wiring board, and a positioning sheet.

In each of the plurality of insulated electric wires, a conductor is exposed from an insulating layer at a tip portion in an axial direction. The printed wiring board has a plurality of connected portions arranged in rows. The tip portions of the plurality of insulated electric wires are respectively soldered to the plurality of connected portions. The positioning sheet has an adhesive layer and a base material film. The adhesive layer is adhered to the tip portions of the plurality of insulated electric wires. The base material film is disposed on the adhesive layer. A longitudinal direction of the positioning sheet extends along a direction in which the plurality of connected portions are arranged (a direction in which the conductors of the plurality of insulated electric wires are arranged).

The connection structure described in PTL 1 is manufactured by the following method. Firstly, a positioning step is performed. In the positioning step, a jig is used. A plurality of positioning grooves are formed in a surface of the jig. A pitch between adjacent two of the plurality of positioning grooves is equal to a pitch between adjacent two of the plurality of connected portions. The tip portions of the plurality of insulated electric wires are respectively disposed in the plurality of positioning grooves.

Secondly, the positioning sheet is bonded to the conductors. On this occasion, the adhesive layer is adhered to the tip portions of the plurality of insulated electric wires. Thirdly, the tip portions of the plurality of insulated electric wires are respectively disposed on the plurality of connected portions, and the adhesive layer at both end portions of the positioning sheet in the longitudinal direction is adhered to the printed wiring board. Fourthly, the tip portions of the plurality of insulated electric wires are respectively soldered to the plurality of connected portions.

### CITATION LIST

### Patent Literature

PTL 1: Japanese Patent Laying-Open No. 2015-201280

### SUMMARY OF INVENTION

A connection structure of the present disclosure includes a plurality of insulated electric wires, a base material, a plurality of connected portions disposed on the base material, and a sealing member. Each of the plurality of insulated electric wires has a central conductor and an insulating layer covering a peripheral surface of the central conductor. The central conductor is exposed from the insulating layer at a tip portion of each of the plurality of insulated electric wires in an axial direction. The plurality of connected portions are arranged in rows. The tip portions of the plurality of insulated electric wires are respectively soldered to the plurality of connected portions. The sealing member is disposed on the base material to cover the tip portions of the plurality of insulated electric wires and the plurality of connected portions.

### BRIEF DESCRIPTION OF DRAWINGS

FIG. 1 is a plan view of a connection structure 100.

FIG. 2 is a cross sectional view taken along II-II in FIG. 1.

FIG. 3 is a cross sectional view taken along III-III in FIG. 1.

FIG. 4 is a cross sectional view taken along IV-IV in FIG. 1.

FIG. 5 is a manufacturing process diagram for connection structure 100.

FIG. 6 is a cross sectional view illustrating a positioning step S2.

FIG. 7 is a cross sectional view illustrating an adhering step S3.

FIG. 8 is a plan view illustrating adhering step S3.

FIG. 9A is a first cross sectional view illustrating a soldering step S4.

FIG. 9B is a second cross sectional view illustrating soldering step S4.

FIG. 9C is a plan view illustrating soldering step S4.

FIG. 10 is a cross sectional view illustrating a peeling step S5.

FIG. 11 is a side view of an insulated electric wire 20 used for connection structure 100 in accordance with a first variation.

FIG. 12 is a cross sectional view taken along XII-XII in FIG. 11.

FIG. 13 is a cross sectional view taken along XIII-XIII in FIG. 11.

FIG. 14 is a cross sectional view of insulated electric wire 20 used for connection structure 100 in accordance with a second variation.

FIG. 15 is a cross sectional view of connection structure 100 in accordance with the second variation.

FIG. 16 is a plan view illustrating soldering step S4 in a method for manufacturing connection structure 100 in accordance with a third variation.

### DETAILED DESCRIPTION

### Problem to be Solved by the Present Disclosure

In the connection structure described in PTL 1, there is a space between the tip portions of adjacent two of the plurality of insulated electric wires. Accordingly, in the connection structure described in PTL 1, there is room for improvement in the reliability of respective connecting portions between the tip portions of the plurality of insulated electric wires and the plurality of connected portions.

The present disclosure has been made in view of the problem of the conventional technique as described above. More specifically, the present disclosure provides a connection structure that can improve the reliability of respective connecting portions between tip portions of a plurality of insulated electric wires and a plurality of connected portions.

### Advantageous Effect of the Present Disclosure

According to the connection structure of the present disclosure, it is possible to improve the reliability of the respective connecting portions between the tip portions of the plurality of insulated electric wires and the plurality of connected portions.

### Summary of Embodiment

Firstly, an embodiment of the present disclosure will be described in list form.

(1) A connection structure in accordance with one embodiment includes a plurality of insulated electric wires, a base material, a plurality of connected portions disposed on the base material, and a sealing member. Each of the plurality of insulated electric wires has a central conductor and an insulating layer covering a peripheral surface of the central conductor. The central conductor is exposed from the insulating layer at a tip portion of each of the plurality of insulated electric wires in an axial direction. The plurality of connected portions are arranged in rows. The tip portions of the plurality of insulated electric wires are respectively soldered to the plurality of connected portions. The sealing member is disposed on the base material to cover the tip portions of the plurality of insulated electric wires and the plurality of connected portions.

According to the connection structure in (1), it is possible to improve the reliability of respective connecting portions between the tip portions of the plurality of insulated electric wires and the plurality of connected portions.

(2) The connection structure in (1) may further include an adhesive. The adhesive may be adhered to a side surface of the tip portion of at least one of the plurality of insulated electric wires.

According to the connection structure in (2), it is possible to suppress mutual mismatch between positions of the tip portions of the plurality of insulated electric wires and positions of the plurality of connected portions during soldering.

(3) In the connection structure in (2), at the tip portion of the at least one of the plurality of insulated electric wires, the adhesive may be adhered to a portion of a peripheral surface of the tip portion where a distance from an upper end of the tip portion is larger than a smaller one of 1/10 of an average diameter of the tip portion and 3 μm.

(4) In the connection structure in (2), at the tip portion of the at least one of the plurality of insulated electric wires, the adhesive may be adhered to a portion of a peripheral surface of the tip portion where a distance from an upper end of the tip portion is larger than a smaller one of ⅓ of an average diameter of the tip portion and 10 μm.

(5) In the connection structure in (1) to (4), a pitch between adjacent two of the plurality of connected portions may be less than or equal to 200 μm.

(6) In the connection structure in (1) to (5), the sealing member located on the tip portions may have a thickness of less than or equal to 100 μm.

According to the connection structure in (6), it is possible to reduce the height of the respective connecting portions between the tip portions of the plurality of insulated electric wires and the plurality of connected portions.

### Details of Embodiment

Details of the embodiment of the present disclosure will be described with reference to the drawings. In the drawings below, identical or corresponding parts will be designated by the same reference numerals, and overlapping description will not be repeated. A connection structure in accordance with the embodiment is referred to as a connection structure 100.

### (Configuration of Connection Structure 100)

A configuration of connection structure 100 will be described below.

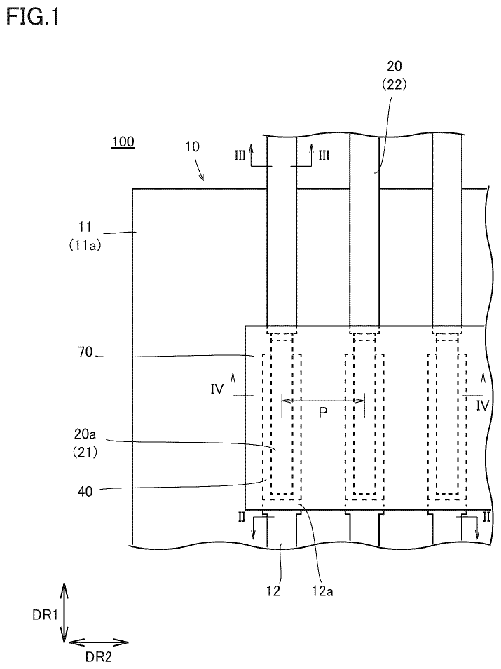

FIG. 1 is a plan view of connection structure 100. As shown in FIG. 1, connection structure 100 has a printed wiring board 10, a plurality of insulated electric wires 20, and a sealing member 70. Although not shown, the plurality of insulated electric wires 20 are obtained by dividing one assembled wire.

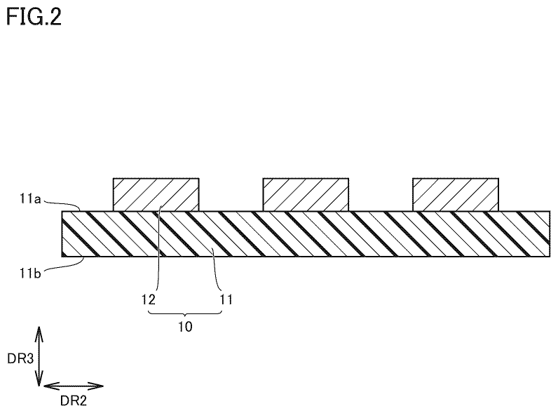

FIG. 2 is a cross sectional view taken along II-II in FIG. 1. As shown in FIG. 2, printed wiring board 10 has a base material 11 and a plurality of wires 12.

Base material 11 has a first main surface 11a and a second main surface 11b. First main surface 11a and second main surface 11b are end surfaces of base material 11 in a thickness direction. Base material 11 is plate-shaped or film-shaped, and is made of an electrically insulating material. Base material 11 is made of a resin material, for example. When base material 11 is plate-shaped, base material 11 is made of glass epoxy or the like, for example. When base material 11 is film-shaped, base material 11 is made of polyimide, polyethylene terephthalate, or the like, for example. The material constituting base material 11 may contain a filler, an additive agent, or the like.

Wires 12 are disposed on first main surface 11a. Wires 12 extend along a first direction DR1 in a plan view. The “plan view” refers to a view when viewed from a direction orthogonal to first main surface 11a. The plurality of wires 12 are arranged with a spacing therebetween in a second direction DR2. Preferably, the plurality of wires 12 are arranged with an equal spacing therebetween in second direction DR2. Second direction DR2 is a direction orthogonal to first direction DR1.

An end portion of each wire 12 in first direction DR1 serves as a connection pad 12a. Connection pad 12a serves as a connected portion to which a tip portion 20a is connected. Connection pads 12a of the plurality of wires 12 are arranged with a spacing therebetween in second direction DR2. Preferably, connection pads 12a of the plurality of wires 12 are arranged with an equal spacing therebetween. A pitch between connection pads 12a of adjacent two of the plurality of wires 12 is referred to as a pitch P. Pitch P is a distance between the center of one connection pad 12a in second direction DR2 and the center of another connection pad 12a adjacent to the one connection pad 12a in second direction DR2. Preferably, pitch P is less than or equal to 200 μm. Although not shown, a surface of connection pad 12a may be subjected to plating such as tin (Sn) plating or gold (Au) plating.

Wires 12 are made of a conductive material. Wires 12 are made of copper (Cu) or a copper alloy, for example. It should be noted that wires 12 are formed, for example, by etching the conductive material disposed on base material 11, using a resist pattern as a mask. However, the method of forming wires 12 is not limited thereto.

A lower limit of an average thickness of wire 12 is preferably 3 μm, and more preferably 5 μm, from the viewpoint of reducing the resistance of wire 12. An upper limit of the average thickness of wire 12 is preferably 100 μm, and more preferably 50 μm, from the viewpoint of reducing the height of connection structure 100.

A lower limit of an average width of connection pad 12a is preferably 0.8 times an average diameter of a central conductor 21, and more preferably 1.0 times the average diameter of central conductor 21, from the viewpoint of ensuring connectivity with central conductor 21. An upper limit of the average width of connection pad 12a is preferably 5.0 times the average diameter of central conductor 21, more preferably 3.0 times the average diameter of central conductor 21, and particularly preferably 2.0 times the average diameter of central conductor 21, from the viewpoint of reducing the width of connection structure 100.

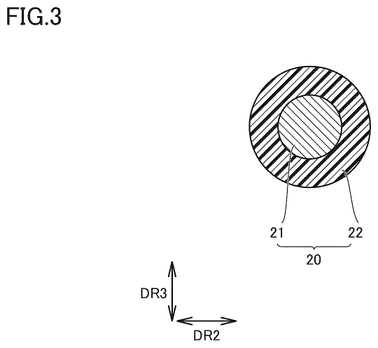

FIG. 3 is a cross sectional view taken along III-III in FIG. 1. As shown in FIG. 3, insulated electric wire 20 has central conductor 21 and an insulating layer 22. Central conductor 21 is made of a conductive material. Central conductor 21 is a metal wire made of copper, a copper alloy, aluminum (Al), an aluminum alloy, or the like, for example. Central conductor 21 is circular, for example, in a cross sectional view orthogonal to an axial direction. The “axial direction” is a direction in which insulated electric wire 20 extends. The cross sectional shape of central conductor 21 is not limited thereto. Central conductor 21 may be square or rectangular, for example.

A lower limit of the average diameter of central conductor 21 is preferably 10 μm, and more preferably 15 μm, from the viewpoint of suppressing breakage of central conductor 21. An upper limit of the average diameter of central conductor 21 is preferably 500 μm, and more preferably 200 μm, from the viewpoint of downsizing connection structure 100.

Insulating layer 22 covers a peripheral surface of central conductor 21. Insulating layer 22 is made of an electrically insulating material having flexibility. Insulating layer 22 is, for example, an ethylene resin, a resin obtained by mixing polyolefin into an ethylene resin, polyimide, polyamide-imide, polyurethane, a silane cross-linked resin composition, a fluorine resin, or the like. Specific examples of the ethylene resin include polyethylene, an ethylene vinyl acetate copolymer, an ethylene ethyl acrylate copolymer, and the like. Specific examples of the polyolefin include polypropylene, an ethylene propylene rubber, a styrene elastomer, and the like. Specific examples of the fluorine resin include polytetrafluoroethylene (PTFE), perfluoroalkoxy alkane (PFA), a perfluoroethylene propene copolymer (FEP), and the like.

Insulating layer 22 is disposed on the peripheral surface of central conductor 21, for example, by extruding the material constituting insulating layer 22 in a melted state onto the peripheral surface of central conductor 21 and curing the same, or applying a coating material obtained by dissolving the material constituting insulating layer 22 in an organic solvent onto the peripheral surface of central conductor 21 and baking the same. Insulating layer 22 has an average thickness of more than or equal to 3 μm and less than or equal to 1 mm, for example.

As shown in FIG. 1, insulated electric wire 20 has tip portion 20a in the axial direction. At tip portion 20a, insulating layer 22 is removed from the peripheral surface of central conductor 21. That is, tip portion 20a is constituted by central conductor 21. An average length of tip portions 20a in the axial direction is more than or equal to 0.2 mm and less than or equal to 3.0 mm, for example.

Although not shown, a primer layer may be interposed between the peripheral surface of central conductor 21 and insulating layer 22 in order to improve adhesiveness between the peripheral surface of central conductor 21 and insulating layer 22. The primer layer is made of a cured cross-linked resin such as ethylene which does not contain a metal hydroxide, for example.

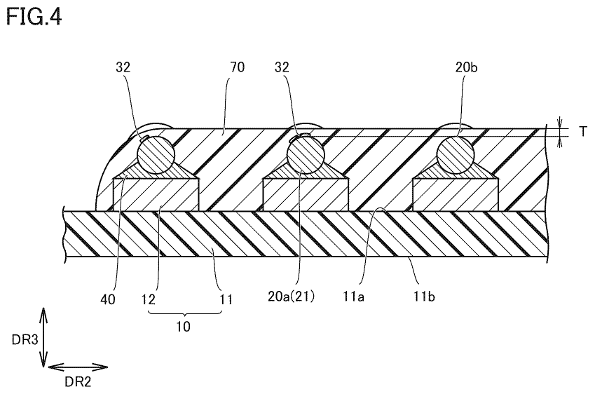

FIG. 4 is a cross sectional view taken along IV-IV in FIG. 1. As shown in FIG. 4, tip portions 20a of the plurality of insulated electric wires 20 are respectively connected to a plurality of connection pads 12a, by connecting portions 40. Connecting portions 40 are made of a solder alloy such as a tin-silver-copper alloy, a tin-zinc (Zn)-bismuth (Bi) alloy, a tin-copper alloy, or a tin-silver-indium (In)-bismuth alloy. That is, tip portions 20a of the plurality of insulated electric wires 20 are respectively soldered to the plurality of connection pads 12a.

Tip portion 20a has an upper end 20b. A distance between tip portion 20a and first main surface 11a in a third direction DR3 is largest at upper end 20b. Third direction DR3 is a direction orthogonal to first direction DR1 and second direction DR2. Third direction DR3 corresponds to a normal direction of first main surface 11a. An adhesive 32 may be adhered to a side surface of tip portion 20a of at least one of the plurality of insulated electric wires 20. Adhesive 32 may be adhered, for example, to a side surface of tip portion 20a of at least one of the plurality of insulated electric wires 20 located at other than both ends in second direction DR2. The expression “adhesive 32 is adhered to a side surface of tip portion 20a” means that adhesive 32 is adhered to a portion of a peripheral surface of tip portion 20a where a distance from upper end 20b in third direction DR3 is larger than a smaller one of 1/10 of an average diameter of tip portion 20a (central conductor 21) and 3 μm. Adhesive 32 may be adhered to a portion of the peripheral surface of tip portion 20a where the distance from upper end 20b in third direction DR3 is larger than a smaller one of ⅓ of the average diameter of tip portion 20a (central conductor 21) and 10 μm.

Sealing member 70 is disposed on first main surface 11a to cover tip portions 20a of the plurality of insulated electric wires 20 and the plurality of connection pads 12a. Sealing member 70 is made of an ultraviolet curable resin material, for example. A thickness of sealing member 70 located on tip portions 20a is referred to as a thickness T. Thickness T is preferably less than or equal to 100 μm.

### (Method for Manufacturing Connection Structure 100)

A method for manufacturing connection structure 100 will be described below.

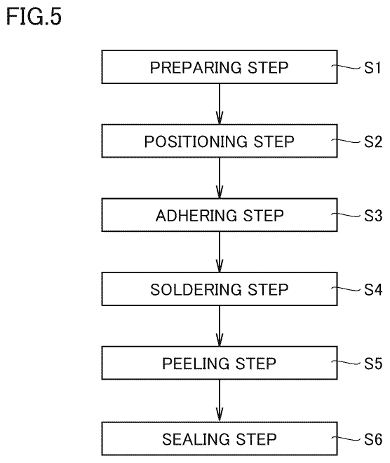

FIG. 5 is a manufacturing process diagram for connection structure 100. As shown in FIG. 5, the method for manufacturing connection structure 100 has a preparing step S1, a positioning step S2, an adhering step S3, a soldering step S4, a peeling step S5, and a sealing step S6. Positioning step S2 is performed after preparing step S1. Adhering step S3 is performed after positioning step S2. Soldering step S4 is performed after adhering step S3. Peeling step S5 is performed after soldering step S4. Sealing step S6 is performed after peeling step S5.

In preparing step S1, the plurality of insulated electric wires 20 are prepared. In preparing step S1, firstly, the plurality of insulated electric wires 20 are divided from an assembled wire. Secondly, insulating layer 22 is removed at tip portion 20a. Removal of insulating layer 22 is performed by emitting a laser to cut insulating layer 22, and peeling off cut insulating layer 22.

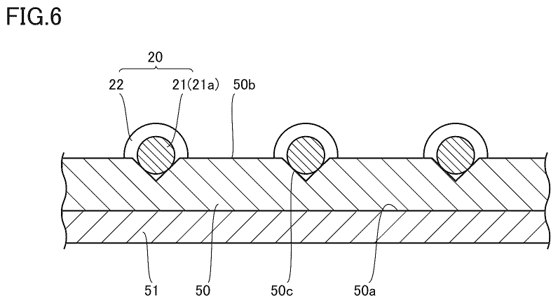

FIG. 6 is a cross sectional view illustrating positioning step S2. As shown in FIG. 6, positioning step S2 is performed using a jig 50. Jig 50 is disposed on a pedestal 51. Jig 50 has a first surface 50a and a second surface 50b. First surface 50a is a surface facing pedestal 51. Second surface 50b is a surface opposite to first surface 50a.

A plurality of positioning grooves 50c are formed in second surface 50b. Each positioning groove 50c linearly extends. Positioning groove 50c is V-shaped, for example, in a cross sectional view orthogonal to a direction in which positioning groove 50c extends. Positioning groove 50c may be U-shaped in the cross sectional view orthogonal to the direction in which positioning groove 50c extends. The plurality of positioning grooves 50c are arranged with a spacing therebetween in a direction orthogonal to the direction in which positioning grooves 50c extend. A pitch between adjacent two of the plurality of positioning grooves 50c is set according to pitch P. In positioning step S2, tip portions 20a of the plurality of insulated electric wires 20 are respectively disposed in the plurality of positioning grooves 50c. Thereby, a pitch between tip portions 20a of adjacent two of the plurality of insulated electric wires 20 is adjusted according to pitch P.

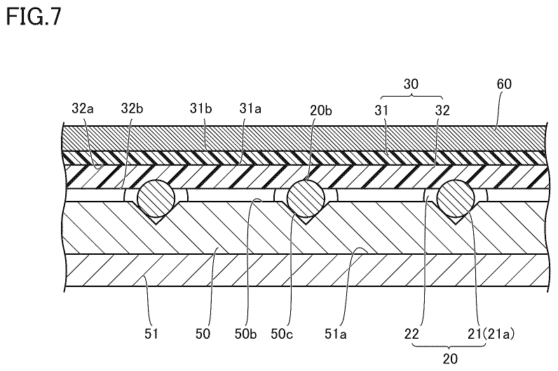

FIG. 7 is a cross sectional view illustrating adhering step S3. As shown in FIG. 7, in adhering step S3, a pitch fixing film 30 is adhered to tip portions 20a of the plurality of insulated electric wires 20, using adhesive 32.

Pitch fixing film 30 has a base material 31 and adhesive 32. Base material 31 is a film-shaped member, for example. Base material 31 has a first main surface 31a and a second main surface 31b. First main surface 31a and second main surface 31b are end surfaces of base material 31 in the thickness direction. First main surface 31a faces base material 11 (printed wiring board 10).

A lower limit of an average thickness of base material 31 is preferably 5 μm, and more preferably 10 μm, from the viewpoint of ensuring the strength of base material 31. An upper limit of the average thickness of base material 31 is preferably 100 μm, and more preferably 50 μm, from the viewpoint of reducing the height of connection structure 100.

Base material 31 is made of a super engineering plastic, for example. Specific examples of the super engineering plastic include polyimide, polyamide-imide, polyetherimide, polyetheretherketone, polyphenylene sulfide, polyarylate, a liquid crystal polymer, polysulfone, polyether sulfone, fluorine resins other than polytetrafluoroethylene, and the like.

Adhesive 32 is disposed as a layer on first main surface 31a. Adhesive 32 has a first surface 32a and a second surface 32b. First surface 32a is a surface in contact with base material 31 (first main surface 31a). Second surface 32b is a surface opposite to first surface 32a. An average thickness of adhesive 32 is smaller than the average thickness of base material 31, for example. A lower limit of the average thickness of adhesive 32 is preferably 5 μm, and more preferably 10 μm, from the viewpoint of ensuring the strength of adhesive 32. The average thickness of adhesive 32 is preferably 100 μm, and more preferably 50 μm, from the viewpoint of reducing the height of connection structure 100.

Adhesive 32 is a thermosetting adhesive containing a thermosetting resin as a main component, for example. The thermosetting resin is an epoxy resin containing a curing agent, for example. Specific examples of the epoxy resin include a bisphenol A type epoxy resin, a bisphenol F type epoxy resin, a bisphenol S-type epoxy resin, a bisphenol AD type epoxy resin, an epoxy resin as a copolymer of bisphenol A type and bisphenol F type epoxy resins, a naphthalene-type epoxy resin, a novolak-type epoxy resin, a biphenyl-type epoxy resin, a dicyclopentadiene-type epoxy resin, and the like. Adhesive 32 only has to contain at least one of these epoxy resins.

When the epoxy resin has a higher molecular weight, there is a tendency that formability is increased and melt viscosity of the resin at a connection temperature is increased. On the other hand, when the epoxy resin has a lower molecular weight, there is a tendency that cross-linking density is increased and heat resistance is improved. Further, when the epoxy resin has a lower molecular weight, there is a tendency that the epoxy resin quickly reacts with the curing agent when heated and adhesion performance is improved. Accordingly, it is preferable that, in the epoxy resin used for adhesive 32, an epoxy resin having a molecular weight of more than or equal to 15000 is combined with an epoxy resin having a molecular weight of less than or equal to 2000. Here, the molecular weight of the epoxy resin is a molecular weight in terms of polystyrene determined from gel permission chromatography (GPC) developed by tetrahydrofuran (THF).

As the curing agent contained in the epoxy resin, a latent curing agent is used, for example. The latent curing agent is a curing agent which is excellent in storage stability at low temperature and rarely causes a curing reaction at room temperature, but quickly causes a curing reaction by heat, light, or the like. Specific examples of the latent curing agent include an imidazole-based compound, a hydrazide-based compound, an amine-based compound such as a boron trifluoride-amine complex, amine imide, a polyamine-based compound, tertiary amine, or an alkylurea-based compound, a dicyandiamide-based compound, an acid anhydride-based compound, and a phenol-based compound, and modified products thereof. As the curing agent for the epoxy resin, one of these compounds and modified products or a mixture of two or more of these compounds and modified products can be used.

As the curing agent contained in the epoxy resin, an imidazole-based latent curing agent is preferable, from the viewpoint of storage stability at low temperature and fast curability. Specific examples of the imidazole-based latent curing agent include an adduct of an imidazole compound to an epoxy resin. Specific examples of the imidazole compound include imidazole, 2-methylimidazole, 2-ethylimidazole, 2-propylimidazole, 2-dodecylimidazole, 2-phenylimidazole, 2-phenyl-4-methylimidazole, 4-methylimidazole, and the like.

Preferably, the imidazole-based latent curing agent is microencapsulated, from the viewpoint of long-term preservability and fast curability. Microcapsules are made of a polymer material, a metal material, or an inorganic material. Specific examples of the polymer material include a polymer material containing polyurethane, polyester, or the like as a main component. Specific examples of the metal material include nickel, copper, and the like. Specific examples of the inorganic material include calcium silicate and the like.

Adhesive 32 may be a thermoplastic adhesive containing a thermoplastic resin as a main component. Specific examples of the thermoplastic resin include polyvinyl acetal such as polyvinyl butyral, a phenoxy resin, an acrylic resin, a methacrylic resin, polyamide, polyacetal, polyphenylene sulfide, polyimide, polytetrafluoroethylene, polyetheretherketone, polyether sulfone, urethane, polyester, polyethylene, polypropylene, polystyrene, and the like. Preferably, the thermoplastic resin is a phenoxy resin, polyamide, polyimide, or the like.

Preferably, base material 31 and adhesive 32 have transparency. Thereby, tip portions 20a can be seen through base material 31 and adhesive 32, and thus manufacturability of connection structure 100 is improved.

Adhesive 32 is adhered to the side surface of tip portion 20a. That is, adhesive 32 is adhered to the portion of the peripheral surface of tip portion 20a where the distance from upper end 20b is larger than the smaller one of 1/10 of the average diameter of tip portion 20a (central conductor 21) and 3 μm. From another viewpoint, a distance between upper end 20b and second surface 32b is larger than the smaller one of 1/10 of the average diameter of tip portion 20a (central conductor 21) and 3 μm.

A lower limit of a thickness of adhesive 32 located between upper end 20b and base material 31 is preferably 1/10 of the average diameter of central conductor 21, and is more preferably ⅕ of the average diameter of central conductor 21, from the viewpoint of fixing central conductor 21 to adhesive 32 more sufficiently. The thickness of adhesive 32 located between upper end 20b and base material 31 is preferably ⅔ of the average diameter of central conductor 21, and is more preferably ½ of the average diameter of central conductor 21, from the viewpoint of reducing the height of connection structure 100. However, upper end 20b may be in contact with base material 31. That is, the lower limit of the thickness of adhesive 32 located between upper end 20b and base material 31 may be 0.

Preferably, the strength of adhesion between tip portion 20a and adhesive 32 is lower than the strength of bonding between tip portion 20a and connection pad 12a.

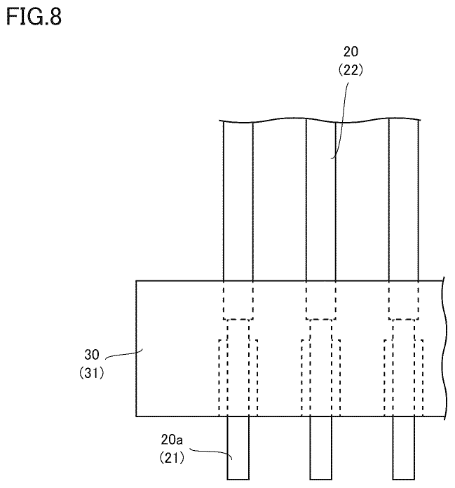

FIG. 8 is a plan view illustrating adhering step S3. As shown in FIG. 8, tip portion 20a protrudes from pitch fixing film 30 in a plan view. A lower limit of a length of tip portion 20a protruding from pitch fixing film 30 is preferably 10 μm, and more preferably 20 μm. An upper limit of the length of tip portion 20a protruding from pitch fixing film 30 is preferably 200 μm, and more preferably 150 μm.

Insulating layer 22 adjacent to tip portion 20a is overlapped with pitch fixing film 30 in the plan view. That is, insulating layer 22 adjacent to tip portion 20a is adhered by adhesive 32. Thereby, a boundary between tip portion 20a and insulating layer 22 adjacent to tip portion 20a is protected by adhesive 32. A lower limit value of a width of an overlap between insulating layer 22 adjacent to tip portion 20a and pitch fixing film 30 is preferably 10 μm, and preferably 20 μm. An upper limit value of the width of the overlap between insulating layer 22 adjacent to tip portion 20a and pitch fixing film 30 is preferably 500 μm, and preferably 300 μm.

In adhering step S3, firstly, pitch fixing film 30 is disposed on tip portions 20a of the plurality of insulated electric wires 20. On this occasion, tip portions 20a of the plurality of insulated electric wires 20 are in contact with adhesive 32. Adhesive 32 is uncured in this stage.

Secondly, a heating body 60 is brought into contact with first main surface 31a, and heating body 60 pressurizes pitch fixing film 30 toward tip portions 20a of the plurality of insulated electric wires 20. Thereby, the side surfaces of tip portions 20a of the plurality of insulated electric wires 20 are adhered to adhesive 32, and tip portions 20a of the plurality of insulated electric wires 20 are fixed to each other. It should be noted that, when adhesive 32 is a thermosetting adhesive, adhesive 32 is B-staged through heating by heating body 60. After adhering step S3 is performed, jig 50 is removed. Since tip portions 20a of the plurality of insulated electric wires 20 are fixed to each other in adhering step S3, the pitch between adjacent two of the plurality of insulated electric wires 20 is less likely to be changed, even after jig 50 is removed.

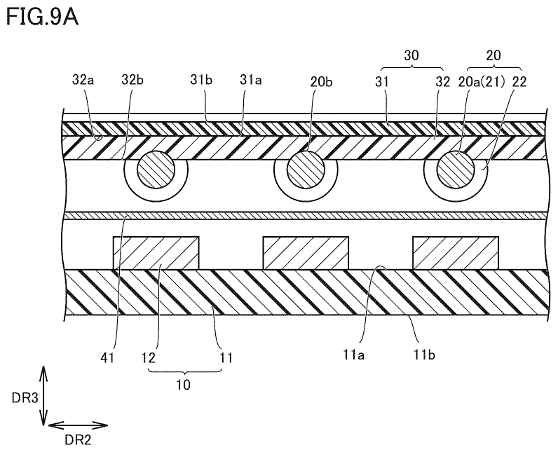

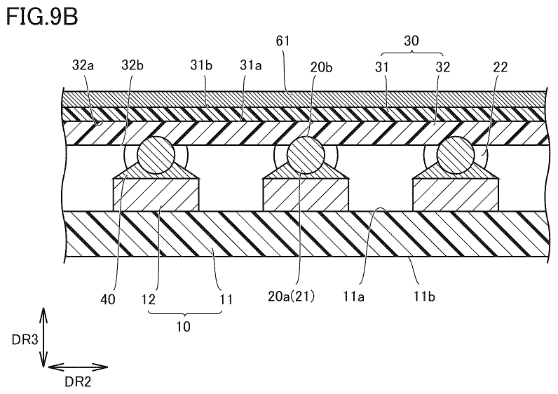

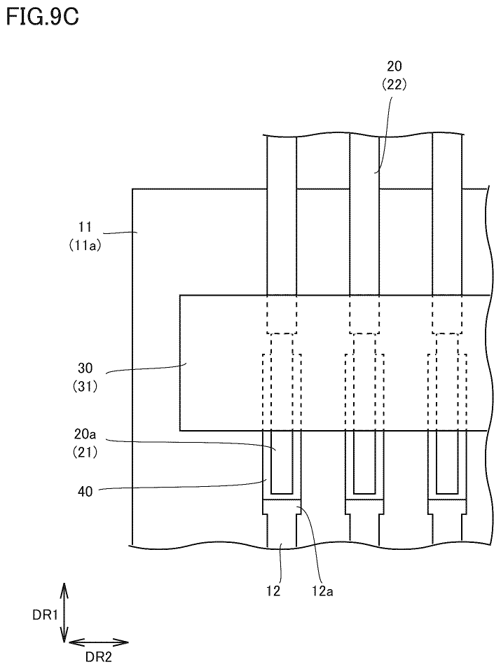

FIG. 9A is a first cross sectional view illustrating soldering step S4. FIG. 9B is a second cross sectional view illustrating soldering step S4. As shown in FIGS. 9A and 9B, in soldering step S4, connecting portions 40 are formed, and tip portions 20a of the plurality of insulated electric wires 20 are respectively soldered to the plurality of connection pads 12a. In soldering step S4, firstly, tip portions 20a of the plurality of insulated electric wires 20 are respectively disposed above the plurality of connection pads 12a, with a plate-shaped solder 41 being interposed therebetween.

The heating temperature in adhering step S3 may be any temperature at which the viscosity of adhesive 32 is decreased to allow each tip portion 20a to be partially buried in adhesive 32. The heating temperature in adhering step S3 is more than or equal to 170° C. and less than or equal to 350° C., for example, and is preferably more than or equal to 200° C. and less than or equal to 320° C. The pressure applied in adhering step S3 may be any pressure at which each tip portion 20a is partially buried in softened adhesive 32. The pressure applied in adhering step S3 is more than or equal to 0.1 MPa and less than or equal to 15 MPa, for example, and is preferably more than or equal to 0.5 MPa and less than or equal to 10 MPa. It should be noted that, if the heating temperature in adhering step S3 and the pressure applied in adhering step S3 are too high, tip portion 20a is buried in adhesive 32 too much (that is, tip portion 20a is covered with adhesive 32), and it becomes impossible to connect tip portion 20a and connection pad 12a. On the other hand, if the heating temperature in adhering step S3 and the pressure applied in adhering step S3 are too low, tip portion 20a is not buried in adhesive 32 (that is, adhesive 32 does not stick to the side surface of tip portion 20a), and a force for maintaining the pitch between tip portions 20a of adjacent two insulated electric wires 20 is weakened.

Secondly, heating body 61 is brought into contact with first main surface 31a, and heating body 61 pressurizes pitch fixing film 30 toward tip portions 20a of the plurality of insulated electric wires 20. Thereby, plate-shaped solder 41 is melted, and tip portions 20a of the plurality of insulated electric wires 20 are respectively soldered to the plurality of connection pads 12a. It should be noted that a rod-shaped solder may be used instead of plate-shaped solder 41. Further, a flux may be supplied to at least one of a surface of plate-shaped solder 41 (rod-shaped solder), a surface of tip portion 20a, and a surface of connection pad 12a. This flux is an organic acid-based or rosin-based flux, for example. Although not shown, soldering may be performed by melting plate-shaped solder 41 (rod-shaped solder) by bringing heating body 61 into contact with second main surface 11b.

FIG. 9C is a plan view illustrating soldering step S4. As shown in FIG. 9C, pitch fixing film 30 at least partially overlaps the plurality of connection pads 12a in a plan view. Both end portions of pitch fixing film 30 in second direction DR2 are located at positions protruding more outward than connection pads 12a which are located outermost in second direction DR2. A lower limit value of a protruding amount of the both end portions of pitch fixing film 30 in second direction DR2 is preferably twice the average diameter of central conductor 21, and is more preferably 2.5 times the average diameter of central conductor 21. An upper limit value of the protruding amount of the both end portions of pitch fixing film 30 in second direction DR2 is preferably 100 times the average diameter of central conductor 21, and is more preferably 50 times the average diameter of central conductor 21. In a stage where soldering step S4 is performed, the both end portions of pitch fixing film 30 in second direction DR2 may be adhered to first main surface 11a, or may not be adhered to first main surface 11a.

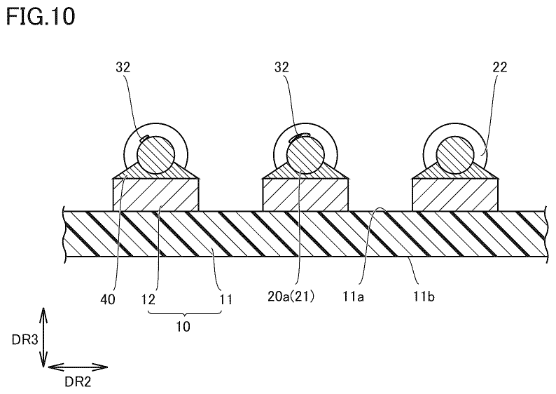

FIG. 10 is a cross sectional view illustrating peeling step S5. As shown in FIG. 10, in peeling step S5, pitch fixing film 30 is peeled off, together with adhesive 32, from tip portions 20a of the plurality of insulated electric wires 20. However, since adhesive 32 may not be completely peeled off even though peeling step S5 is performed, adhesive 32 may partially remain at the side surface of tip portion 20a of at least one of the plurality of insulated electric wires 20.

In sealing step S6, tip portions 20a of the plurality of insulated electric wires 20 and the plurality of connection pads 12a are covered with sealing member 70. In sealing step S6, firstly, sealing member 70 is supplied onto first main surface 11a to cover tip portions 20a of the plurality of insulated electric wires 20 and the plurality of connection pads 12a. Sealing member 70 is uncured in this stage. Secondly, ultraviolet rays are emitted to uncured sealing member 70. Thereby, sealing member 70 is cured, and tip portions 20a of the plurality of insulated electric wires 20 and the plurality of connection pads 12a are sealed with sealing member 70. In this manner, connection structure 100 with the structure shown in FIGS. 1 to 4 is formed.

### (Effect of Connection Structure 100)

The effect of connection structure 100 will be described below.

In connection structure 100, since sealing member 70 is disposed on first main surface 11a to cover tip portions 20a of the plurality of insulated electric wires 20 and the plurality of connection pads 12a, sealing member 70 is also provided to between tip portions 20a of adjacent two of the plurality of insulated electric wires 20. Accordingly, according to connection structure 100, the connecting portions between tip portions 20a and connection pads 12a can have a higher reliability.

If only upper ends 20b of tip portions 20a of the plurality of insulated electric wires 20 are adhered to adhesive 32 as described in PTL 1, fixing of positions of tip portions 20a of the plurality of insulated electric wires 20 may be insufficient. As a result, when soldering is performed, the positions of tip portions 20a of the plurality of insulated electric wires 20 may be respectively displaced from positions of the plurality of connection pads 12a, and a failure may occur in soldering. This is particularly significant when pitch P is small (for example, when pitch P is less than or equal to 200 μm).

On the other hand, in connection structure 100, adhesive 32 is adhered to the side surfaces of tip portions 20a of the plurality of insulated electric wires 20 in adhering step S3. Accordingly, in connection structure 100, the positions of tip portions 20a of the plurality of insulated electric wires 20 are fixed more firmly by adhesive 32. As a result, according to connection structure 100, when soldering is performed, the positions of tip portions 20a of the plurality of insulated electric wires 20 are less likely to be respectively displaced from the positions of the plurality of connection pads 12a, and occurrence of a failure in soldering can be suppressed.

In connection structure 100, pitch fixing film 30 is peeled off from tip portions 20a of the plurality of insulated electric wires 20. However, when soldering step S4 is completed, there is no need to fix tip portions 20a of the plurality of insulated electric wires 20 to each other by adhesive 32. Accordingly, in connection structure 100, pitch fixing film 30 is peeled off after soldering step S4 is completed. Thus, even though connection structure 100 does not have pitch fixing film 30, the positions of tip portions 20a of the plurality of insulated electric wires 20 are suppressed from being respectively displaced from the positions of the plurality of connection pads 12a when soldering is performed.

It should be noted that, in the connection structure described in PTL 1, the adhesive layer at the both end portions of the positioning sheet in the longitudinal direction is adhered to the printed wiring board, for more reliable connection between the tip portions of the insulated electric wires and the connected portions. Accordingly, in the connection structure described in PTL 1, peeling off the positioning sheet from the tip portions of the insulated electric wires is not assumed.

In connection structure 100, since pitch fixing film 30 is peeled off, connection structure 100 can have a reduced height because it does not have pitch fixing film 30. It should be noted that, although a portion where tip portion 20a is connected to connection pad 12a has a larger height in connection structure 100 because it has sealing member 70, having a reduced height is not hindered as long as thickness T is less than or equal to 100 μm.

### First Variation

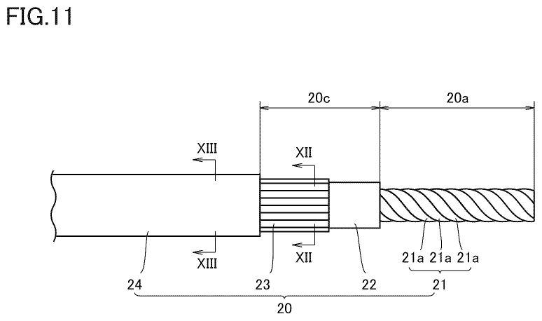

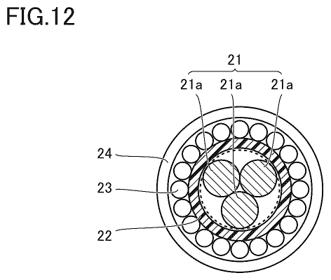

FIG. 11 is a side view of insulated electric wire 20 used for connection structure 100 in accordance with a first variation. FIG. 12 is a cross sectional view taken along XII-XII in FIG. 11. As shown in FIGS. 11 and 12, central conductor 21 may be a twisted wire obtained by twisting a plurality of element wires 21a. In this case, the average diameter of tip portion 20a is determined based on a virtual circumscribed circle (indicated by a dotted line in FIG. 12) circumscribed around the plurality of element wires 21a, and whether adhesive 32 is adhered to the side surface of tip portion 20a is determined based on the average diameter of tip portion 20a determined based on the circumscribed circle. It should be noted that the number of element wires 21a constituting central conductor 21 is more than or equal to 2 and less than or equal to 20, for example, although it is not particularly limited.

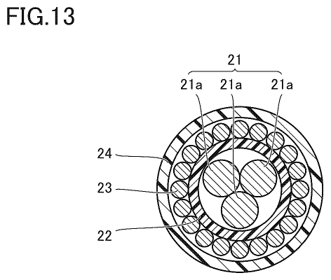

FIG. 13 is a cross sectional view taken along XIII-XIII in FIG. 11. As shown in FIG. 13, insulated electric wire 20 may further have a plurality of outer conductors 23 and an outer sheath 24. That is, insulated electric wire 20 may be a coaxial wire. Each outer conductor 23 is a metal wire made of copper or a copper alloy, for example. The metal wire having a surface plated with silver, tin, or the like may be used as outer conductor 23. Outer conductors 23 extend along the axial direction on a peripheral surface of insulating layer 22. Outer conductors 23 may be spirally wound. The plurality of outer conductors 23 are arranged along the peripheral surface of insulating layer 22, and thereby cover insulating layer 22. The cross sectional shape of outer conductor 23 is circular, square, rectangular, or the like, for example.

A lower limit of an average diameter of outer conductor 23 is preferably 10 μm, and more preferably 15 μm, from the viewpoint of suppressing breakage of outer conductor 23. An upper limit of the average diameter of outer conductor 23 is preferably 500 μm, and more preferably 200 μm, from the viewpoint of suppressing insulated electric wire 20 from having a too large outer diameter.

Outer sheath 24 covers the plurality of outer conductors 23. Outer sheath 24 is made of an electrically insulating material having flexibility. Outer sheath 24 is made of a polyester resin such as polyethylene terephthalate, for example. Outer sheath 24 may be made of the same material as that of insulating layer 22. Insulated electric wire 20 has an adjacent portion 20c which is adjacent to tip portion 20a in the axial direction. At tip portion 20a, insulating layer 22, the plurality of outer conductors 23, and outer sheath 24 are removed, and thereby central conductor 21 is exposed. At adjacent portion 20c, outer sheath 24 is removed, and thereby the plurality of outer conductors 23 are exposed. It should be noted that, at a portion of adjacent portion 20c close to tip portion 20a, the plurality of outer conductors 23 are also removed.

The plurality of outer conductors 23 exposed at adjacent portion 20c are electrically connected to a ground line (not shown) disposed on first main surface 11a, for example, by soldering or the like, to have a ground potential, and thereby function as a shield for suppressing electric interference from other circuits. An average length of adjacent portion 20c in the axial direction is more than or equal to 0.1 mm and less than or equal to 5 mm, for example.

When insulated electric wire 20 has the plurality of outer conductors 23 and outer sheath 24, in preparing step S1, outer sheath 24 at tip portion 20a and adjacent portion 20c and the plurality of outer conductors 23 at tip portion 20a are removed before insulating layer 22 at tip portion 20a is removed.

### Second Variation

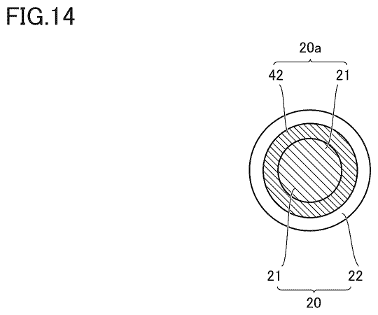

FIG. 14 is a cross sectional view of insulated electric wire 20 used for connection structure 100 in accordance with a second variation. As shown in FIG. 14, tip portion 20a may be constituted by central conductor 21 and a solder layer 42 covering central conductor 21. In this case, an average diameter of solder layer 42 and an upper end of solder layer 42 respectively serve as the average diameter and upper end 20b of tip portion 20a, and whether adhesive 32 is adhered to the side surface of tip portion 20a is determined based on these. It should be noted that solder layer 42 is formed by supplying a melted solder alloy onto the peripheral surface of central conductor 21 at tip portion 20a, after insulating layer 22 is removed in preparing step S1.

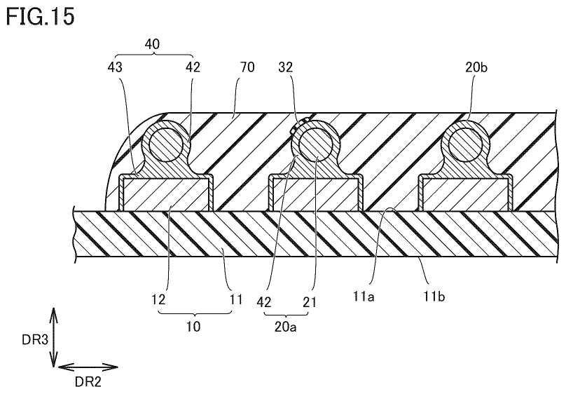

FIG. 15 is a cross sectional view of connection structure 100 in accordance with the second variation. FIG. 15 shows a cross section of connection structure 100 in accordance with the second variation, at a position corresponding to FIG. 4. As shown in FIG. 15, the surface of connection pad 12a may be covered with a solder layer 43. Solder layer 43 is formed by plating the surface of connection pad 12a, for example. Solder layer 42 and solder layer 43 are bonded to each other by heating in soldering step S4, to constitute connecting portion 40. It should be noted that, when tip portion 20a has solder layer 42 and the surface of connection pad 12a is covered with solder layer 43, plate-shaped solder 41 (rod-shaped solder) is not used in soldering step S4, and the flux is supplied to at least one of a surface of solder layer 42 and a surface of solder layer 43.

### Third Variation

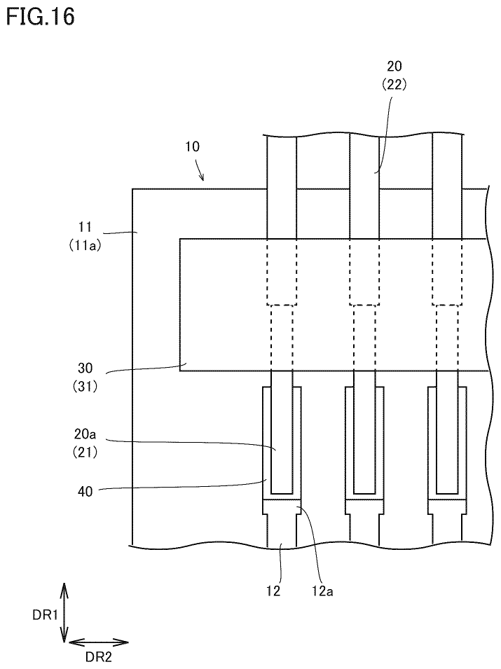

FIG. 16 is a plan view illustrating soldering step S4 in the method for manufacturing connection structure 100 in accordance with a third variation. As shown in FIG. 16, pitch fixing film 30 does not have to overlap the plurality of connection pads 12a in a plan view.

### Fourth Variation

Adhesive 32 does not have to be disposed beforehand on base material 31. That is, in adhering step S3, base material 31 may be bonded onto adhesive 32 after adhesive 32 is adhered to tip portions 20a of the plurality of insulated electric wires 20.

It should be understood that the embodiment disclosed herein is illustrative and non-restrictive in every respect. The scope of the present invention is defined by the scope of the claims, rather than the embodiment described above, and is intended to include any modifications within the scope and meaning equivalent to the scope of the claims.

### REFERENCE SIGNS LIST

10: printed wiring board; 11a: first main surface; 11b: second main surface; 11: base material; 12: wire; 12a: connection pad; 20: insulated electric wire; 20a: tip portion; 20b: upper end; 20c: adjacent portion; 21: central conductor; 21a: element wire; 22: insulating layer; 23: outer conductor; 30: pitch fixing film; 31: base material; 31a: first main surface; 31b: second main surface; 32: adhesive; 32a: first surface; 32b: second surface; 40: connecting portion; 41: plate-shaped solder; 42, 43: solder layer; 50: jig; 50a: first surface; 50b: second surface; 50c: positioning groove; 51: pedestal; 60: heating body; 61: heating body; 70: sealing member; 100, 200, 300: connection structure; DR1: first direction; DR2: second direction; DR3: third direction; P: pitch; S1: preparing step; S2: positioning step; S3: adhering step; S4: soldering step; S5: peeling step; S6: sealing step; T: thickness.

1. A connection structure comprising:
a plurality of insulated electric wires;
a base material;
a plurality of connected portions disposed on the base material; and
a sealing member, wherein
each of the plurality of insulated electric wires has a central conductor and an insulating layer covering a peripheral surface of the central conductor,
the central conductor is exposed from the insulating layer at a tip portion of each of the plurality of insulated electric wires in an axial direction,
the plurality of connected portions are arranged in rows,
the tip portions of the plurality of insulated electric wires are respectively soldered to the plurality of connected portions, and
the sealing member is disposed on the base material to cover the tip portions of the plurality of insulated electric wires and the plurality of connected portions.

2. The connection structure according to claim 1, further comprising an adhesive, wherein
the adhesive is adhered to a side surface of the tip portion of at least one of the plurality of insulated electric wires.

3. The connection structure according to claim 2, wherein, at the tip portion of the at least one of the plurality of insulated electric wires, the adhesive is adhered to a portion of a peripheral surface of the tip portion where a distance from an upper end of the tip portion is larger than a smaller one of 1/10 of an average diameter of the tip portion and 3 μm.

4. The connection structure according to claim 2, wherein, at the tip portion of the at least one of the plurality of insulated electric wires, the adhesive is adhered to a portion of a peripheral surface of the tip portion where a distance from an upper end of the tip portion is larger than a smaller one of ⅓ of an average diameter of the tip portion and 10 μm.

5. The connection structure according to claim 1, wherein a pitch between adjacent two of the plurality of connected portions is less than or equal to 200 μm.

6. The connection structure according to claim 1, wherein the sealing member located on the tip portions of the plurality of insulated electric wires has a thickness of less than or equal to 100 μm.
